(19) United States
(12) Patent Application Publication
(10) Pub. No.: US 2005/0249946 A1
(43) Pub. Date: Nov. 10, 2005

(54) Protection film and method of making the same

(75) Inventors: Shih-Chuan Hsu, Chungli City (TW); Hsiu-Min Feng, Pinchen City (TW); Pi-Chuan Yang, Taipei (TW)

Correspondence Address: BRUCE H. TROXELL, SUITE 1404, 5205 LEESBURG PIKE, FALLS CHURCH, VA, 22041, US

(73) Assignee: Optimax Technology Corporation

(21) Appl. No.: 11/099,641

(22) Filed: Apr. 6, 2005

(30) Foreign Application Priority Data
May 7, 2004 (TW) 93112845

(51) Int. Cl. B32B 7/12; H01L 23/62

(52) U.S. Cl. 428/353; 428/354; 428/483

(57) ABSTRACT

The present inventions provide a protection film and the method of making the same. The protection film comprises a substrate, made of a compound selected from the group consisting of polycarbonate (PC), polyethylene (PE), polypropylene (PP), and aryl polyester (PET); an adhesive layer, attached on at least one of the surfaces of the substrate; and an acrylic primer, arranged between the substrate and the adhesive layer for enhancing the cohesiveness. The protection film not only has a better anti-stress capability, but also is capable of reduce the thickness of the adhesive layer so as to reduce the manufacturing cost of the protection film.

### FIELD OF THE INVENTION

The present inventions relate to a protection film and the method of making the same, and more particularly, to a multi-layer protection film for display, which uses an acrylic primer arranged between a substrate and an adhesive layer of the protection film to improve the cohesiveness and reduce the consumption of the adhesive layer.

### BACKGROUND OF THE INVENTION

Nowadays, monitors or screens have seemingly become increasingly essential for our daily life, e.g. people can gain a variety of knowledge by watching television programs and thus enrich our daily life. By the progress of multimedia technology used on computer, it is possible for use to deal with a large number of information for database management, process control, affair simulation, trend prediction and even creation of literatures and art works through the computer monitors, that works as a catalyst capable of increasing the pace of human life. The displays currently in use have at least one layer of clear protection film that has functions of anti-scratch and anti-smudge. A known screen protection film, which is usually known as screen protector, comprises at least a substrate, an adhesive layer, and a release film. The protection film is attached to the release film while not used, and is released while being attached to a monitor.

The substrate is the major structure of the protection films, which can be made of a material selected from the group consisting of polycarbonate (PC), polyethylene (PE), oriented polypropylene (OPP), and aryl polyester (PET), and works as a basic layer to be coated with a variety of function layers. The adhesive layer, usually made of silicones, is coated on a side of the substrate for attaching the protection film onto a display. The thickness of the substrate is the matter of concern. On one hand, it is too rigid to keep flat when the substrate is attached to the monitor if the substrate is too thick and on the other hand, it is too hard to keep wrinkle-free for attaching and releasing from release and safe from crash of an external protrusion if the substrate is too thin. Moreover, since the poor cohesiveness between the substrate and silicone adhesion layer can result in the poor durability of the protection film that is easy to peel from the display, and from an economic point of view for making the protection film, the adhesive layer of the protection films must have a certain thickness (approximately 25 μm˜30 μm), which takes up quite a few manufacturing cost of the protection film, it is important to take care of lowering the cost by reducing the consumption of the adhesion layer and simultaneously improving the cohesiveness between the substrate and the adhesive layer.

To meet the problems and shortcomings of the current protection film for displays, it is an object of the present invention to provide a protection film and the method of making the same.

### SUMMARY OF THE INVENTION

It is therefore an object of the present invention to provide a protection film and the method of making the same. The protection film comprises a substrate and an adhesive layer and an acrylic primer arranged between the substrate and the adhesive layer for improving the cohesiveness and enabling the protection film to have better anti-stress capability.

Another object of the invention is to provide a protection film and the method of making the same that employs an acrylic primer arranged between the substrate and the adhesive layer to improve the cohesiveness so as to reduce the thickness of the adhesive layer and consequently reduce the manufacturing cost of the protection films.

Following drawings are cooperated to describe the detailed structure and its connective relationship according to the invention for facilitating your esteemed members of reviewing committee in understanding the characteristics and the objectives of the invention.

### BRIEF DESCRIPTION OF THE DRAWINGS

FIG. 1 is a partial enlarged sectional view of the first preferred embodiment of the present invention.

FIG. 2 is a partial enlarged sectional view of the second preferred embodiment of the present invention.

FIG. 3 is a partial enlarged sectional view of the third preferred embodiment of the present invention.

FIG. 4 is a schematic diagram showing a method for coating the adhesive layer and primer according to the present invention.

FIG. 5 is a schematic diagram showing a method for coating the self-healing clear film of the present invention.

FIG. 6 is the numerator structure of the self-healing clear film of the present invention.

FIG. 7 is a flow chart depicting a method of making the protection film according a preferred embodiment of the present invention.

### DESCRIPTION OF THE PREFERRED EMBODIMENT

For your esteemed members of reviewing committee to further understand and recognize the fulfilled functions and structural characteristics of the invention, several preferable embodiments cooperating with detailed description are presented as the follows.

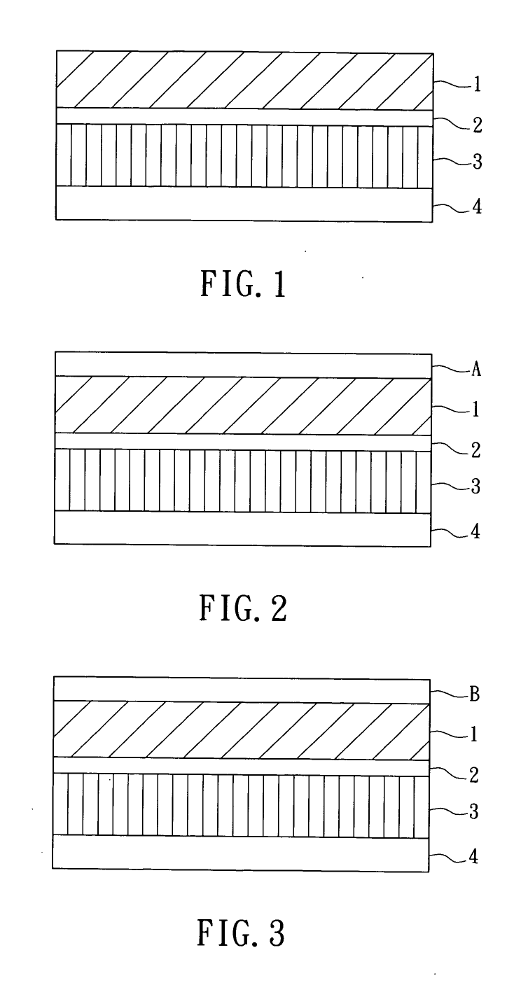

Please refer to FIG. 1, which is a partial enlarged sectional view of the first preferred embodiment of the present invention. The protection films of the present invention can be adapted as the optical films applied to the display of computer, LCD television set, cell phone and vehicle navigation device, and so on. The protection film comprises at least a substrate 1, an adhesive layer 3, and a primer 2. The substrate 1 is made of a material selected from the group consisting of polycarbonate (PC), polyethylene (PE), OPP, and aryl polyester (PET), and the thickness of the substrate 1 is between 75 μm and 188 μm, which is preferred to be approximately 100 μm. If the substrate 1 is too thin, the protection film will not be able to provide enough protection to the display where the film is attached and the display is vulnerable to foreign object, in addition, it is also hard to keep wrinkle-free for attaching and releasing the protection film the display. If the substrate 1 is too thick, the protection film will be too rigid to follow the curve of the display where it is attached without forming bulge pattern thereon, moreover, from economic point of view, it is preferred not to spend too much manufacturing cost on the substrate.

One of the surfaces of the substrate 1 is coated with a layer of primer 2. The primer is a compound formed by mixing a base polymer of the derivative of acrylic acid, such as the acrylic resin, epoxy and polyurethane resin (PU), with a proper crosslinker and a catalyst while diluting the mixing in an organic solvent, such as toluene. The primer 2 is capable of being coated on the substrate 1. The coating of the primer 2 is about 10 μm to 15 μm thick. Following, the adhesive layer 3 is being coated on top of the primer 2. The cohesiveness between the substrate 1 and the adhesive layer 3 is greatly improved by the addition layer of the acrylic adhesive primer 2, such that the consumption and the thickness of the adhesive layer 3 can be reduced to half, in addition, the manufacturing cost can be reduced since the cost of the primer 2 is not as expensive as the adhesive layer 3. Therefore, the cost of making protection films can be reduced substantially. The release film used in the present invention can be a non-silicones type release film 4, made of a material selected from the group consisting of polyethylene PET, OPP, and PE.

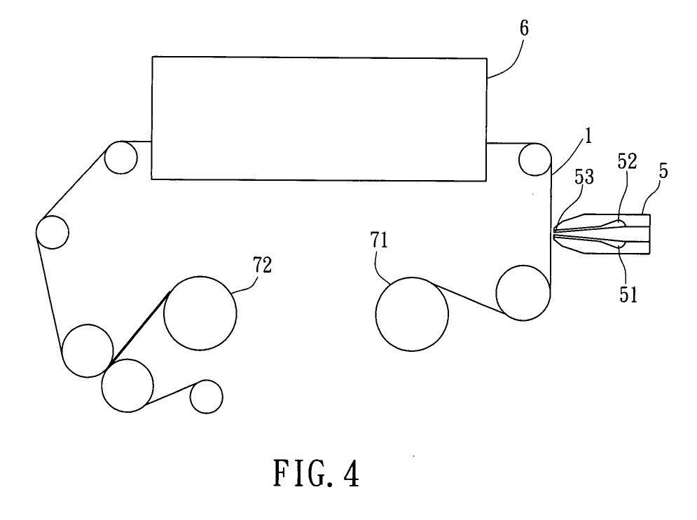

As seen in FIG. 4, the method for making the protection film according to a first preferred embodiment of the present invention includes the steps of:
a. selecting an aromatic polyester to be the base polymer of substrate 1, which is preferred to be a product of polyethylene terephthalate, such as Toray T-60 PET of Toray Japan or T-600 PET of Mitsubishi Japan.
b. Transporting the substrate 1 using the rollers as seen in FIG. 4 for coating the substrate 1 with a layer of 15 μm thick acrylic primer by a first coating head 51 of a coating device 5, as the substrate 1 is being transported to the coating device 5. Moreover, the acrylic primer 2 can be “AT-240” of Soken Corp., which is diluted using toluene as solvent.
c. Coating a layer of 15 μm thick silicone adhesive layer 3 on top of the acrylic primer 2 by a second coating head 53 of the coating device. Moreover, the adhesive layer 3 can be “7210” of Dow Coming Corp. Taiwan, which is diluted using toluene as solvent.
d. Transporting the substrate 1 coated with both the acrylic primer 2 and the silicon adhesive layer 3 into an oven 6 to be cured under a drying process of 150° C. for one minute.
e. Attaching a release film 4 onto the cured substrate 1 for forming the protection film of the present invention.
f. Attaching other function films on a surface of the substrate 1 opposite to the surface thereof coated with the primer 2.

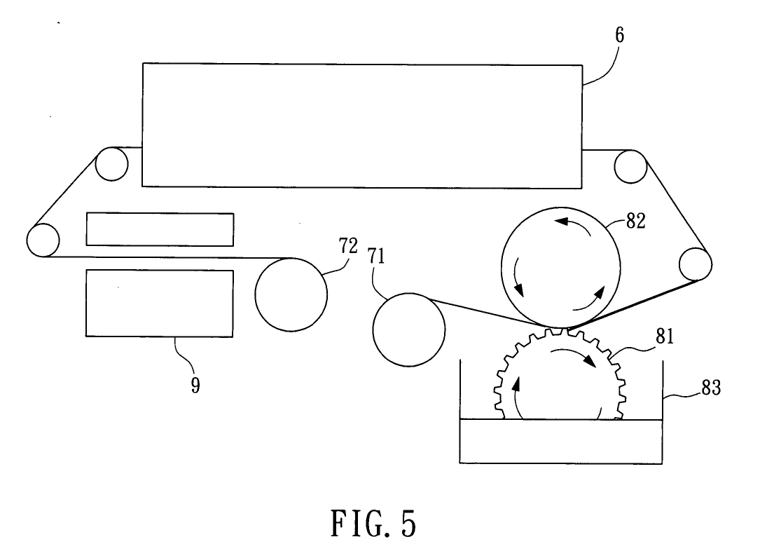

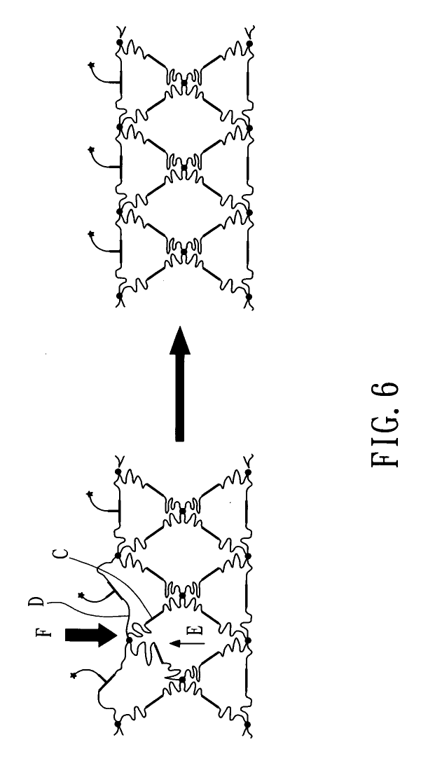

Please refer to FIG. 1 and FIG. 6 for a second preferred embodiment of the present invention. The difference between the first embodiment and the second embodiment is that the surface of the substrate 1 without the primer 2 is attached to a self-healing clear film. The self-healing clear film having low surface friction coefficient is capable of generating a recover force E to resist the deformation caused by an external force F while it is subjected to the external force F. In the preferred embodiment, the self-healing clear film is made of “RT-1S” of NATOCO, Japan. Please refer to FIG. 5, the compound of the self-healing clear film A is filled in the container 83 and the protection film of the first embodiment is rolled out to a space between an engraved roller 81 and a pressure roller 82 by a first rolling device 71. The pressure roller 82 and the spread roller 81 are rolled with opposite direction. Since the engraved roller 82 is formed with bulging sawteeth, it is capable of bringing up the compound of the self-healing clear film A to be coated on the substrate 1. The thickness of the self-healing clear film A is approximate 20 μm which is first being dried in room temperature and then being cured by a UV device 9 with 300 mj/cm² UV light. After the curing process is finished, the protection film is rolled into a second rolling device 72.

Please refer to FIG. 3 for a third preferred embodiment of the present invention. The difference between the first embodiment and the second embodiment is that the surface of the substrate 1 without the primer 2 is attached to an anti-glare layer B. The anti-glare film is approximately 6 μm thick and is made of a compound formed by mixing a photoinitiator, a leveling composition, nano-particles and a diluting solvent with predetermined ratio. The compound of the anti-glare film B is coated on the surface of the substrate 1 without the primer 2 to be dried in a 70° C. oven 6 and then cured by a 150W UV light. The anti-glare film B has a plurality of particles that can improve the scattering effect of the protection film where it is attached, therefore, the display attached with anti-glare protection film can prevent the glare from hurting user's vision.

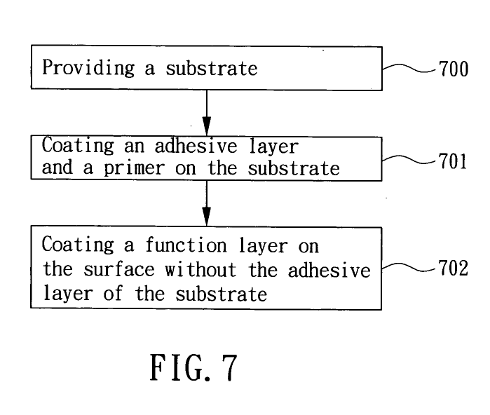

Please refer to FIG. 7, which is a flow chart depicting a method of making the protection film according a preferred embodiment of the present invention. The method comprises the steps of:
Step 700: providing a substrate 1, wherein the common substrate used by the industry is made of PC, PE, OPP, or aryl polyester (PET).
Step 701: coating an adhesive layer 3 and a primer 2 onto the substrate 1, wherein the primer 2 is sandwiched between the substrate 1 and the adhesive layer 3 as seen in FIG. 1. A derivative of acrylic acid, that is, being commonly referred as acrylic resin, can be used as the primer 2 for improving the cohesiveness between the substrate 1 and the adhesive layer 3. Furthermore, since the cost of the primer 2 is not as expensive as the adhesive layer 3, while using the primer 2 to replace a portion of the adhesive layer 3 enabling the thickness and the consumption of the adhesive layer to be reduced at least by half, not only the cohesiveness between the substrate 1 and the adhesive layer 3 can be improved, but also the manufacturing cost of the protection film is reduced.
Step 702: coating a function layer on the surface without the adhesive layer of the substrate. A function layer is coated on the surface without the primer 2 of the substrate 1 according to the practice use of the invention (as shown in FIG. 2 and FIG. 3). The function layer can be a self-healing clear film A or an anti-glare film B. The self-healing clear film having low surface friction coefficient is capable of generating a recover force E to resist the deformation caused by an external force F while it is subjected to the external force F. The anti-glare film B has a plurality of particles that can improve the scattering effect of the protection film where it is attached, therefore, the display attached with anti-glare protection film can prevent the glare from hurting user's vision.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

1. A protection film, comprising:
a substrate, made of a compound selected from the group consisting of polycarbonate (PC), polyethylene (PE), polypropylene (PP), and aryl polyester (PET),
an adhesive layer, attached on at least one of surfaces of said substrate, and
a primer, arranged between said substrate and said adhesive layer, made of a compound selected from the group consisting of acrylic resin, epoxy and polyurethane resin.

2. The protection film of claim 1, wherein a preferred compound for said substrate is polyethylene terephthalate.

3. The protection film of claim 1, wherein said adhesive layer is made of silicones.

4. The protection film of claim 1, wherein a self-healing clear film is coated on one surface of said substrate without said adhesive layer, and said self-healing clear film having low surface friction coefficient is capable of reducing the deformation caused by an external force.

5. The protection film of claim 4, wherein the compound of said self-healing clear film being coated on said substrate requires to be cured by an UV light.

6. The protection film of claim 1, wherein an anti-glare film is coated on one surface of said substrate without said adhesive layer, and said anti-glare film comprises a plurality of particles for improving the scattering effect of said protection film.

7. The protection film of claim 6, wherein the curing process of said anti-glare film requires said anti-glare film to be dried by a predetermined temperature and then cured by an UV light.

8. A method for making a protection film, comprising the steps of:
(a) providing a substrate, wherein the substrate is made of a compound selected from the group consisting of polycarbonate (PC), polyethylene (PE), polypropylene (PP), and aryl polyester (PET);
(b) coating a primer and an adhesive layer onto said substrate, wherein said primer is sandwiched between said substrate and said adhesive layer and said primer is a compound selected from the group consisting of a derivative of acrylic, epoxy and polyurethane resin.

9. The method of claim 8, wherein said method further comprises a step (c) after step (b):
coating a function layer on the surface of said substrate without said primer.

10. The method of claim 8, wherein a preferred compound for said substrate is polyethylene terephthalate.

11. The method film of claim 8, wherein said derivative of acrylic is acrylic resin.

12. The method film of claim 9, wherein said function layer is a anti-glare film.

13. The method of claim 12, wherein the curing process of said anti-glare film requires said anti-glare film to be dried by a predetermined temperature and then cured by an UV light.

14. The method film of claim 9, wherein said function layer is a self-healing clear film.

15. The method of claim 14, wherein said self-healing clear film being coated on said substrate requires to be cured by an UV light.
